(19) United States
(12) Patent Application Publication
(10) Pub. No.: US 2023/0088046 A1
(43) Pub. Date: Mar. 23, 2023

(54) Method for Manufacturing Integrated Metal Resistance Layer

(71) Applicant: Shanghai Huali Integrated Circuit Corporation, Shanghai (CN)

(72) Inventors: Changhung Kung, Shanghai (CN); Shaojia Zhu, Shanghai (CN); Mingfei Yu, Shanghai (CN); Jianxun Chen, Shanghai (CN); Chanyuan Hu, Shanghai (CN)

(73) Assignee: Shanghai Huali Integrated Circuit Corporation, Shanghai (CN)

(21) Appl. No.: 17/877,324

(22) Filed: Jul. 29, 2022

(30) Foreign Application Priority Data
Sep. 18, 2021 (CN) 202111097917.4

(51) Int. Cl. H01L 49/02

(52) U.S. Cl. CPC H01L 28/20

(57) ABSTRACT

The present application provides a method for manufacturing an integrated metal resistance layer, comprising: step 1, selecting a formation position of a metal resistance layer, wherein the formation position of the metal resistance layer is located on the surface of an interlayer film inlaid with a copper connection; step 2, completing formation processes of the selected copper connection and the selected interlayer film; step 3, forming the metal resistance layer, comprising the following sub-steps: step 31, depositing a material layer of the metal resistance layer; and step 32, performing patterned etching on the material layer of the metal resistance layer to form the metal resistance layer in the selected region; and step 4, forming a next copper connection and a via at the bottom of the next copper connection, wherein the vias at the bottom of the next copper connection have two different heights.

### CROSS-REFERENCES TO RELATED APPLICATIONS

This application claims priority to Chinese Patent application No. 202111097917.4, filed on Sep. 18, 2021, the disclosure of which is incorporated herein by reference in its entirety.

### TECHNICAL FIELD

The present application relates to a method for manufacturing a semiconductor integrated circuit, in particular to a method for manufacturing an integrated metal resistance layer.

### BACKGROUND

In the existing advanced logic chip process, a high resistance (Hi-R) layer is a key element for reducing voltage and current in a circuit design. In the existing method, a high resistance layer is realized by means of a metal resistance layer, and the metal resistance layer used for realizing the high resistance layer is referred to as a high resistance metal layer (Hi-R metal layer). The existing high-resistance metal layer is formed in a zeroth interlayer film i.e., an inner dielectric layer, between a contact plug and a gate structure, thus increasing the difficulty in process control.

The following description is made with reference to FIG. 1. Referring to FIG. 1, which is a schematic structural diagram of a device formed by an existing method for manufacturing an integrated metal resistance layer, in the existing method for manufacturing an integrated metal resistance layer, a metal resistance layer 108 is integrated in a zeroth interlayer film 107 on the top of a gate structure 105. The description is as follows:

A front end of line (FEOL) structure is formed on a semiconductor substrate 101.

The semiconductor substrate 101 includes a silicon substrate.

The front end of line process includes steps of forming the gate structure 105 on the semiconductor substrate 101 and forming a source region and a drain region on two sides of the gate structure 105. The semiconductor substrate 101 is usually integrated with both NMOS and PMOS. Both the NMOS and PMOS are formed in respective active regions, and it is necessary to form shallow trench isolation 102 to define the active region. An N-type well 103 is formed in a formation region of the PMOS, and a P-type well 104 is formed in a formation region of the NMOS.

The gate structure 105 includes a gate dielectric layer and a gate conductive material layer stacked in sequence, and the gate dielectric layer is a gate oxide layer or a high dielectric constant layer.

A spacer 106 is formed on the side surface of the gate structure 105. The source region and the drain region are self-aligned with the spacer 106.

The zeroth interlayer film 107 is formed in a plurality of steps. During the process of forming the zeroth interlayer film 107, at a position where the zeroth interlayer film 207 is grown to be higher than the top surface of the gate structure 105, a process of forming the metal resistance layer 108 is performed.

The process of forming the metal resistance layer 108 includes the following:

A material layer of the metal resistance layer 108 is deposited, wherein the resistivity of the material layer of the metal resistance layer 108 is greater than the resistivity of copper. The material layer of the metal resistance layer 108 includes a titanium nitride layer or a cobalt layer. Generally, a step of depositing a silicon nitride layer 109 is performed after the material layer of the metal resistance layer 108 is deposited.

The patterned etching is performed on the material layer of the metal resistance layer 108 to form the metal resistance layer 108 in a selected region.

Then, the growth of the zeroth interlayer film 107 continues until it reaches a desired thickness.

Etching and filling of an opening of a contact plug 110 are performed to form the contact plug 110. Metal forming the contact plug 110 is usually metal tungsten.

A copper interconnection process is performed subsequently, wherein the copper interconnection includes a plurality of copper connections and a via at the bottom of the copper connection. Two copper connections are shown in FIG. 1. As the bottom of the first copper connection 113a is in contact with the contact plug 110, no via is formed at the bottom of the first copper connection 113a, and therefore the first copper connection 113a is usually formed by means of a single damascene process. In the process of forming the first copper connection 113a, a first carbon-doped silicon nitride (NDC) layer 112a and a first interlayer film 111a are formed firstly, wherein the first NDC layer 112a is used to prevent copper from diffusing between upper and lower interlayer films. After that, photolithography and etching processes are performed to form a trench of the first copper connection 113a, then a barrier layer and metal copper are formed in the trench, and a chemical mechanical polishing process is performed to form the first copper connection 113a.

Subsequently, a second copper connection 113b and a via 114b at the bottom of the second copper connection are formed by means of a dual damascene process. In the dual damascene process, a second NDC layer 112b and a second interlayer film 111b are formed firstly. Generally, the first interlayer film 111a and the second interlayer film 111b are both formed of low dielectric constant materials, so as reduce parasitic capacitance. A silicon oxide layer 115b can be formed between the second NDC layer 112b and the second interlayer film 111b.

Then a trench of the second copper connection 113b and an opening of the via 114b are formed. After that, a barrier layer and metal copper are formed in the trench of the second copper connection 113b and the opening of the via 114b at the same time, and a chemical mechanical polishing process is performed to simultaneously form the second copper connection 113b and the via 114b.

The existing method causes the following difficulty in process control:

If the distance between the metal resistance layer 108 and the gate structure 105 is excessively small, as indicated by the dashed line circle 116a, there is a short circuit risk.

If the distance between the metal resistance layer 108 and the gate structure 105 is increased under the condition that the thickness of the zeroth interlayer film 107 is kept unchanged, the thickness of a region indicated by the dashed line circle 116b may be reduced. In this case, the distance between the metal resistance layer 108 and the first copper connection 113a is reduced, also leading to a short circuit risk.

Moreover, if the distance between the metal resistance layer 108 and the gate structure 105 and the distance between the metal resistance layer 108 and the first copper connection 113a are increased at the same time, the thickness of the zeroth interlayer film 107 is necessarily increased. In this case, the aspect ratio of the contact plug 110 at the position indicated by the dashed line circle 116c is increased, affecting the performance of filling the via with the metal tungsten, and eventually leading to a metal plug open circuit risk and affecting the product yield.

It can be seen from the above description that process windows indicated by the dashed line circles 116a, 116b, and 116c in the existing method are relatively small, and the difficulty in process control is relatively large.

### BRIEF SUMMARY

The technical problem to be solved by the present application is to provide a method for manufacturing an integrated metal resistance layer, so as to reduce the difficulty and risk in process control and expand the selectivity of a circuit design.

According to some embodiments in this application, the method for manufacturing an integrated metal resistance layer provided by the present application includes the following steps:

step 1, selecting a formation position of a metal resistance layer, wherein the formation position of the metal resistance layer is located on the surface of an interlayer film inlaid with a copper connection in a back end of line process, an interlayer film below the metal resistance layer is a selected interlayer film, a copper connection embedded in the selected interlayer film is a selected copper connection, and the selected copper connection is selected from a first copper connection to a sub-top copper connection;

step 2, completing formation processes of the selected copper connection and the selected interlayer film on a semiconductor substrate;

step 3, forming the metal resistance layer, including the following sub-steps:

step 31, depositing a material layer of the metal resistance layer, wherein the resistivity of the material layer of the metal resistance layer is greater than the resistivity of copper;

and

step 32, performing patterned etching on the material layer of the metal resistance layer to form the metal resistance layer in the selected region, wherein the formation region of the metal resistance layer is located on the surface of the selected interlayer film; and

step 4, forming a next copper connection and a via at the bottom of the next copper connection, wherein the vias at the bottom of the next copper connection have two different heights, and the height of the via on the top of the metal resistance layer is less than the height of the via on the top of the selected copper connection.

In some cases, the semiconductor substrate provided in step 2 undergoes a front end of line process, a middle of line process, and the back end of line process before formation of the selected copper connection.

In some cases, a zeroth interlayer film and a contact plug passing through the zeroth interlayer film are formed in the middle of line process.

In some cases, the bottom of the first copper connection is connected to the contact plug.

In some cases, the first copper connection is formed by means of a single damascene process.

In some cases, each copper connection above the first copper connection and a via at the bottom of the same are formed by means of a dual damascene process.

In some cases, in step 31, the material layer of the metal resistance layer includes a first titanium nitride layer or a second cobalt layer.

In some cases, before depositing the material layer of the metal resistance layer in step 31, the method further includes a step of depositing a third diffusion barrier layer.

In some cases, the third diffusion barrier layer is a carbon-doped silicon nitride (NDC) layer.

In some cases, in step 32, the patterned etching of the material layer of the metal resistance layer stops at the third diffusion barrier layer.

In some cases, after depositing the material layer of the metal resistance layer in step 31, the method further includes a step of depositing a fourth silicon oxide layer.

In some cases, the thickness of the first titanium nitride layer is 50-150 nm; and

the thickness of the second cobalt layer is 10-50 nm.

In some cases, in step 4, an etching process of an opening of the via at the bottom of the next copper connection stops at the surface of the selected copper connection or the metal resistance layer, so as to form the vias of two different heights at the bottom of the next copper connection.

In some cases, in step 32, a selected region of the patterned etching is defined by means of a photolithography process.

In some cases, in step 4, simultaneously forming the next copper connection and the via at the bottom of the next copper connection by means of a dual damascene process includes the following sub-steps:

forming a next interlayer film;

forming a trench of the next copper connection and the opening of the via at the bottom of the next copper connection in the next interlayer film, the opening of the via at the bottom of the next copper connection being located at the bottom of the trench of the next copper connection; and

forming a barrier layer and metal copper, and performing chemical mechanical polishing to obtain the next copper connection composed of the metal copper filling the trench of the next copper connection and the via composed of the metal copper filling the opening of the via at the bottom of the next copper connection.

In some cases, the front end of line process includes step of forming a gate structure on the semiconductor substrate and forming a source region and a drain region on two sides of the gate structure.

Different from the prior art in which the metal resistance layer is disposed in the zeroth interlayer film between the top surface of the gate structure and the bottom surface of the first copper connection, the present application configures the formation position of the metal resistance layer on the surface of an interlayer film inlaid with a copper connection in the back end of line process, so that in a next layer process with respect to the metal resistance layer, only two vias of different heights need to be formed, while other processes do not need to be changed. Therefore, the present application can ensure that the metal resistance layer imposes no adverse effect on the front end of line process and the middle of line process, and eventually can reduce the difficulty and risk in process control and expand the selectivity of a circuit design.

### BRIEF DESCRIPTION OF THE DRAWINGS

The present application is described in detail below with reference to the drawings and specific implementations:

FIG. 1 is a schematic structural diagram of a device formed by an existing method for manufacturing an integrated metal resistance layer.

FIG. 2 is a flowchart of a method for manufacturing an integrated metal resistance layer according to an embodiment of the present application.

FIGS. 3A-3G are diagrams of device structures in steps of the method for manufacturing an integrated metal resistance layer according to an embodiment of the present application.

### DETAILED DESCRIPTION OF THE DISCLOSURE

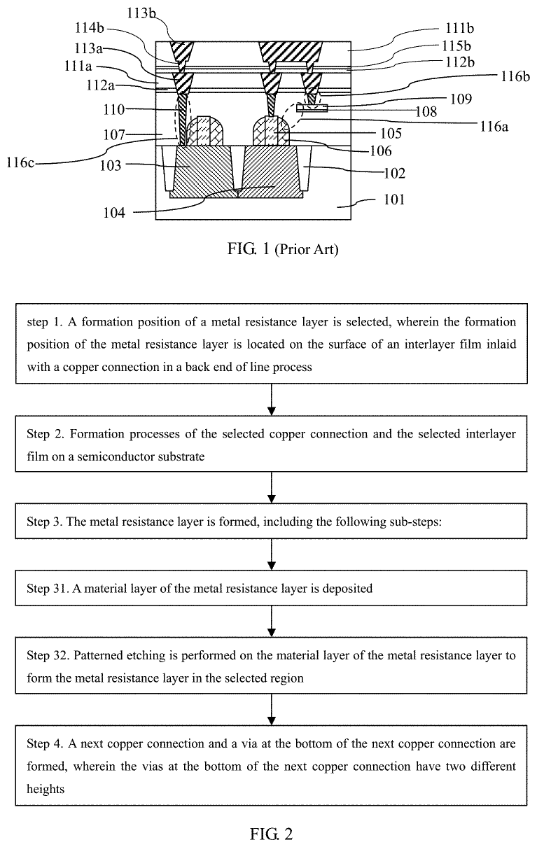

Referring to FIG. 2, which is a flowchart of a method for manufacturing an integrated metal resistance layer 212 according to an embodiment of the present application, the method for manufacturing the integrated metal resistance layer 212 according to the embodiment of the present application includes the following steps:

Step 1. A formation position of a metal resistance layer 212 is selected, wherein the formation position of the metal resistance layer 212 is located on the surface of an interlayer film inlaid with a copper connection in a back end of line process, an interlayer film below the metal resistance layer is a selected interlayer film, a copper connection embedded in the selected interlayer film is a selected copper connection, and the selected copper connection is selected from a first copper connection 211a to a sub-top copper connection.

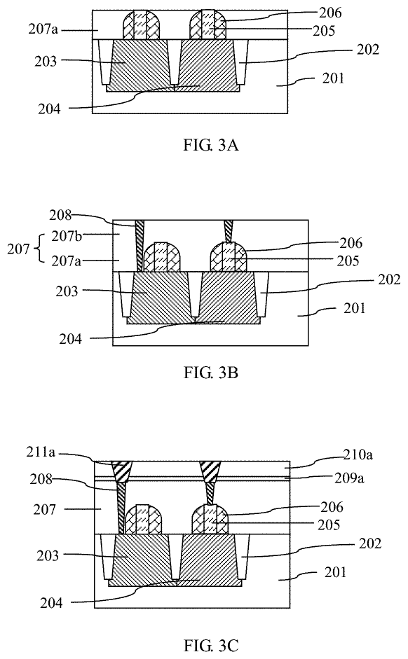

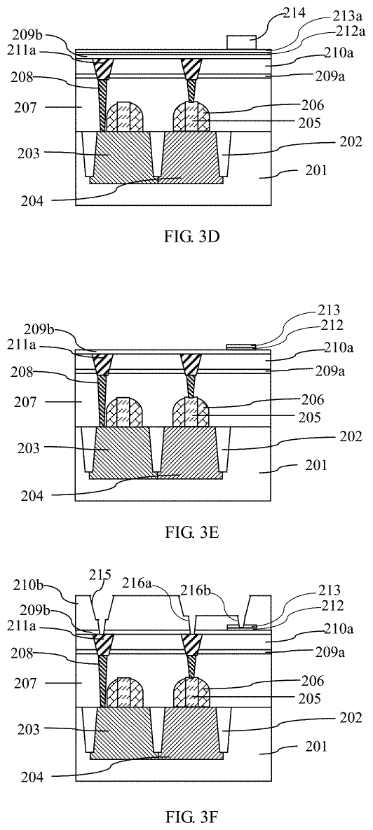

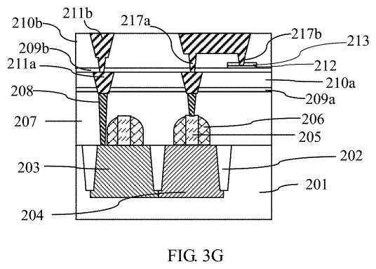

Step 2. Referring to FIG. 3A, formation processes of the selected copper connection and the selected interlayer film on a semiconductor substrate 201.

In the method of this embodiment of the present application, the first copper connection 211a is used as the selected copper connection to perform description. The selected interlayer film is a first interlayer film 210a.

The semiconductor substrate 201 undergoes a front end of line process, a middle of line process, and the back end of line process before formation of the selected copper connection.

The semiconductor substrate 201 includes a silicon substrate.

The front end of line process includes steps of forming a gate structure 105 on the semiconductor substrate 201 and forming a source region and a drain region on two sides of the gate structure 105. The semiconductor substrate 201 is usually integrated with both NMOS and PMOS. Both the NMOS and PMOS are formed in respective active regions, and it is necessary to form shallow trench isolation 102 to define the active region. An N-type well 203 is formed in a formation region of the PMOS, and a P-type well 204 is formed in a formation region of the NMOS.

The gate structure 205 includes a gate dielectric layer and a gate conductive material layer stacked in sequence, and the gate dielectric layer is a gate oxide layer or a high dielectric constant layer. The gate conductive material layer is a polysilicon gate or a metal gate. The specific structures of the gate dielectric layer and the gate conductive material layer can be selected according to actual requirements of the NMOS and PMOS. For example, the gate dielectric layer of an input-output device may be a gate oxide layer, and the gate dielectric layer of a core device may be a high dielectric constant layer. The gate conductive material layers of the NMOS and PMOS both can be polysilicon gates. Alternatively, the gate conductive material layers of the NMOS and PMOS both are metal gates, but materials of work function layers in the metal gates of the NMOS and PMOS are N-type work function layer and P-type work function layer, respectively.

A spacer 206 is formed on the side surface of the gate structure 205. The source region and the drain region are self-aligned with the spacer 206.

If the gate conductive material layer is a metal gate, a gate replacement process is required. Before the gate replacement, the gate conductive material layer is replaced with a dummy polysilicon gate, and then the spacer and the source and drain regions are formed until a bottom portion 207a of a zeroth interlayer film 207 is formed. The top surface of the bottom portion 207a of the zeroth interlayer film 207 is flush with the surface of the dummy polysilicon gate; and then the dummy polysilicon gate is removed and the metal gate is formed in a region where the dummy gate polysilicon is removed.

Referring to FIG. 3B, then the middle of line process is performed, wherein the zeroth interlayer film 207 and a contact plug 208 passing through the zeroth interlayer film 207 are formed in the middle of line process. The zeroth interlayer film 207 is formed by stacking the bottom portion 207a and a top portion 207b, wherein the top portion 207b of the zeroth interlayer film 207 needs to be formed in the middle of line process, and the top portion 207b of the zeroth interlayer film 207 is located above the top surface of the gate structure 205. The contact plug 208 is formed after the top surface of the zeroth interlayer film 207 is planarized, and the contact plug 208 is formed on the top of lead-out positions of the gate structure 205, the source region, and the drain region. The sectional view shown in FIG. 3B shows two contact plugs 208, wherein the contact plug 208 located on the top of the gate structure 205 passes through only the top portion 207b of the zeroth interlayer film 20, and the contact plug 208 located on the top of the source region or the drain region passes through the entire zeroth interlayer film 207.

Referring to FIG. 3C, the first copper connection 211a is formed after the contact plug 208 is formed. The bottom of the first copper connection 211a is connected to the contact plug 208. Since the bottom of the first copper connection 211a is directly connected to the contact plug 208, no via is formed at the bottom of the first copper connection 211a. Therefore, the first copper connection 211a is formed by means of a single damascene process.

In the single damascene process of forming the first copper connection 211a, a carbon-doped silicon nitride layer 209a is formed firstly. The carbon-doped silicon nitride layer 209a is used to prevent copper from diffusing between upper and lower interlayer films, i.e., the zeroth interlayer film 207 and the subsequent first interlayer film 210a.

Then the first interlayer film 210a is formed, and the first interlayer film 210a is usually composed of a low dielectric constant material (ULK). The low dielectric constant material includes black diamond (BD), wherein composition elements of the black diamond include silicon, oxygen, carbon, and hydrogen.

Subsequently, photolithography definition is performed, and an etching process is performed on the first interlayer film 210a and the carbon-doped silicon nitride layer 209a to form a trench.

Then, the trench is filled with a barrier layer and metal copper, and a chemical mechanical polishing process is performed to form the first copper connection 211a composed of the metal copper filling the trench.

Step 3. The metal resistance layer 212 is formed, including the following sub-steps:

Step 31. Referring to FIG. 3D, a material layer 212a of the metal resistance layer 212 is deposited, wherein the resistivity of the material layer 212a of the metal resistance layer 212 is greater than the resistivity of copper.

In the method of this embodiment of the present application, the material layer 212a of the metal resistance layer 212 includes a first titanium nitride layer or a second cobalt layer. That is, the material layer 212a of the metal resistance layer 212 may be composed of the first titanium nitride layer or the second cobalt layer, or may be formed by stacking the first titanium nitride and the second cobalt layer.

The thickness of the first titanium nitride layer is 50-150 nm.

The thickness of the second cobalt layer is 10-50 nm.

In some examples, the method further includes a step of depositing a third diffusion barrier layer 209b before depositing the material layer 212a of the metal resistance layer 212. The third diffusion barrier layer 209b is a carbon-doped silicon nitride layer. The third diffusion barrier layer 209b can prevent the diffusion of copper between the upper and lower interlayer films.

The method further includes a step of depositing a fourth silicon oxide layer 213a after depositing the material layer 212a of the metal resistance layer 212.

Step 32. Patterned etching is performed on the material layer 212a of the metal resistance layer 212 to form the metal resistance layer 212 in the selected region, wherein the formation region of the metal resistance layer 212 is located on the surface of the selected interlayer film.

In this embodiment of the present application, the selected region of the patterned etching is defined by a pattern of a photoresist 214 formed by means of a photolithography process.

Referring to FIG. 3E, the patterned etching of the material layer 212a of the metal resistance layer 212 stops at the third diffusion barrier layer 209b.

It can be seen that, after the metal resistance layer 212 is formed, the top surface of the metal resistance layer 212 is higher than the top surface of the first copper connection 211a.

Step 4. A next copper connection and a via at the bottom of the next copper connection are formed, wherein the vias at the bottom of the next copper connection have two different heights, and the height of the via on the top of the metal resistance layer 212 is less than the height of the via on the top of the selected copper connection.

Referring to FIG. 3G in this embodiment of the present application, since the first copper connection 211a is selected as the selected copper connection, the next copper connection is a second copper connection 211b. The height of the via 217b at the top of the metal resistance layer 212 is less than the height of the via 217a at the top of the second copper connection 211b. That is, under the condition that the top surfaces of the vias 217a and 217b are flush with each other, the bottom surface of the via 217a is lower, so that the height between the top surface and the bottom surface of the via 217a is greater than the height between the top surface and the bottom surface of the via 217b.

Referring to FIG. 3F, an etching process of openings 216a and 216b of the vias at the bottom of the second copper connection 211b stops at the surface of the selected copper connection or the metal resistance layer 212, so as to form the vias of two different heights at the bottom of the next copper connection.

Since vias are formed at the bottom of each copper connection above the first copper connection, each copper connection above the first copper connection and a via at the bottom of the same are formed by means of a dual damascene process. A formation process of each copper connection above the second copper connection and a via at the bottom of each copper connection above the second copper connection is similar to the formation process of the second copper connection 211b and vias 217a and 217b at the bottom of the second copper connection. The following description is carried out using only the formation process of the second copper connection 211b and the vias 217a and 217b at the bottom of the second copper connection as an example.

In step 4, simultaneously forming the next copper connection and the via at the bottom of the next copper connection by means of a dual damascene process includes the following sub-steps:

Referring to FIG. 3F, a next interlayer film, i.e., a second interlayer film 210b, is formed.

A trench 215 of the next copper connection and the openings 216a and 216b of the vias at the bottom of the next copper connection are formed in the next interlayer film. The openings 216a and 216b of the vias at the bottom of the next copper connection are located at the bottom of the trench of the next copper connection, wherein the opening 216a is located on the top of the first copper connection 211a, and the opening 216b is located on the top of the metal resistance layer 212.

Referring to FIG. 3G a barrier layer and metal copper are formed, and chemical mechanical polishing is performed to obtain the second copper connection 211b composed of the metal copper filling the trench 215 of the second copper connection 211b and the vias 217s and 217b composed of the metal copper filling the openings 216a and 216b of the vias at the bottom of the second copper connection 211b.

Different from the prior art in which the metal resistance layer is disposed in the zeroth interlayer film between the top surface of the gate structure and the bottom surface of the first copper connection, the present application configures the formation position of the metal resistance layer 212 on the surface of an interlayer film inlaid with a copper connection in the back end of line process, so that in a next layer process with respect to the metal resistance layer 212, only two vias of different heights need to be formed, while other processes do not need to be changed. Therefore, the present application can ensure that the metal resistance layer 212 imposes no adverse effect on the front end of line process and the middle of line process, and eventually can reduce the difficulty and risk in process control and expand the selectivity of a circuit design.

The present application is described in detail above by using specific embodiments, which, however, are not intended to limit the present application. Without departing from the principles of the present application, those skilled in the art can also make many modifications and improvements, which should also be regarded as the scope of protection of the present application.

What is claimed is:

1. A method for manufacturing an integrated metal resistance layer, comprising the following steps:
step 1, selecting a formation position of a metal resistance layer, wherein the formation position of the metal resistance layer is located on a surface of an interlayer film inlaid with a copper connection in a back end of line process, an interlayer film below the metal resistance layer is a selected interlayer film, a copper connection embedded in the selected interlayer film is a selected copper connection, and the selected copper connection is selected from a first copper connection to a sub-top copper connection;
step 2, completing formation processes of the selected copper connection and the selected interlayer film on a semiconductor substrate;
step 3, forming the metal resistance layer, comprising the following sub-steps:
step 31, depositing a material layer of the metal resistance layer, wherein a resistivity of the material layer of the metal resistance layer is greater than a resistivity of copper; and
step 32, performing patterned etching on the material layer of the metal resistance layer to form the metal resistance layer in the selected region, wherein the formation region of the metal resistance layer is located on the surface of the selected interlayer film; and
step 4, forming a next copper connection and a via at a bottom of the next copper connection, wherein the vias at the bottom of the next copper connection have two different heights, and a height of the via on the top of the metal resistance layer is less than a height of the via on the top of the selected copper connection.

2. The method for manufacturing the integrated metal resistance layer according to claim 1, wherein the semiconductor substrate provided in step 2 undergoes a front end of line process, a middle of line process, and the back end of line process before formation of the selected copper connection.

3. The method for manufacturing the integrated metal resistance layer according to claim 2, wherein a zeroth interlayer film and a contact plug passing through the zeroth interlayer film are formed in the middle of line process.

4. The method for manufacturing the integrated metal resistance layer according to claim 3, wherein the bottom of the first copper connection is connected to the contact plug.

5. The method for manufacturing the integrated metal resistance layer according to claim 4, wherein the first copper connection is formed by means of a single damascene process.

6. The method for manufacturing the integrated metal resistance layer according to claim 4, wherein each copper connection above the first copper connection and a via at the bottom of the same are formed by means of a dual damascene process.

7. The method for manufacturing the integrated metal resistance layer according to claim 1, wherein in step 31, the material layer of the metal resistance layer comprises a first titanium nitride layer or a second cobalt layer.

8. The method for manufacturing the integrated metal resistance layer according to claim 7, before depositing the material layer of the metal resistance layer in step 31, further comprising a step of depositing a third diffusion barrier layer.

9. The method for manufacturing the integrated metal resistance layer according to claim 8, wherein the third diffusion barrier layer is a carbon-doped silicon nitride layer.

10. The method for manufacturing the integrated metal resistance layer according to claim 8, wherein in step 32, the patterned etching of the material layer of the metal resistance layer stops at the third diffusion barrier layer.

11. The method for manufacturing the integrated metal resistance layer according to claim 7, after depositing the material layer of the metal resistance layer in step 31, further comprising a step of depositing a fourth silicon oxide layer.

12. The method for manufacturing the integrated metal resistance layer according to claim 7, wherein a thickness of the first titanium nitride layer is 50-150 nm, and a thickness of the second cobalt layer is 10-50 nm.

13. The method for manufacturing the integrated metal resistance layer according to claim 7, wherein in step 4, an etching process of an opening of the via at the bottom of the next copper connection stops at the surface of the selected copper connection or the metal resistance layer, so as to form the vias of two different heights at the bottom of the next copper connection.

14. The method for manufacturing the integrated metal resistance layer according to claim 1, wherein in step 32, a selected region of the patterned etching is defined by means of a photolithography process.

15. The method for manufacturing the integrated metal resistance layer according to claim 13, wherein in step 4, simultaneously forming the next copper connection and the via at the bottom of the next copper connection by means of a dual damascene process comprises the following sub-steps:
forming a next interlayer film;
forming a trench of the next copper connection and the opening of the via at the bottom of the next copper connection in the next interlayer film, the opening of the via at the bottom of the next copper connection being located at the bottom of the trench of the next copper connection; and
forming a barrier layer and metal copper, and performing chemical mechanical polishing to obtain the next copper connection composed of the metal copper filling the trench of the next copper connection and the via composed of the metal copper filling the opening of the via at the bottom of the next copper connection.

16. The method for manufacturing the integrated metal resistance layer according to claim 2, wherein the front end of line process comprises step of forming a gate structure on the semiconductor substrate and forming a source region and a drain region on two sides of the gate structure.
